(19) United States
(12) Patent Application Publication
(10) Pub. No.: US 2002/0191657 A1
(43) Pub. Date: Dec. 19, 2002

(54) Semiconductor lasers with improved coupling efficiency

(76) Inventor: Kishore K. Kamath, Whitehall Township, PA (US)

Correspondence Address: Docket Administrator, Agere Systems Inc., P.O. Box 614, Berkeley Heights, NJ, 07922-0614, US

(21) Appl. No.: 09/883,034

(22) Filed: Jun. 15, 2001

(51) Int. Cl. H01S 5/00

(52) U.S. Cl. 372/45

(57) ABSTRACT

The invention is a semiconductor laser, laser module, and method of manufacture. The laser includes an active region having a first refractive index, and at least one confinement layer with a second refractive index, which is lower than the first refractive index. An anti-guiding layer having a third refractive index which is lower than the second refractive index is positioned so that the confinement layer is between the active region and the anti-guiding layer. A cladding layer having a fourth refractive index which is greater than the third refractive index is positioned so that the anti-guiding layer is between the cladding layer and the confinement layer.

### FIELD OF THE INVENTION

This invention relates to semiconductor lasers, and in particular to a structure and method of manufacture which improves coupling of light from such lasers into an optical fiber or other optical waveguide.

### BACKGROUND OF THE INVENTION

Optical systems have become the backbone of modern telecommunications systems primarily due to their tremendous information-handling capacity. Such systems typically include one or more semiconductor lasers as an optical source, and optical fiber as the transmission medium. Another key component is the optical amplifier, which includes a rare earth -doped fiber whose impurities are excited by another laser (pump laser) in order to provide amplification of the optical signal from the source. Another type of optical amplifier is the Raman amplifier, which also relies on pump light for amplification. While the remainder of this application will focus primarily on these pump lasers, it should be realized that the invention is applicable to any semiconductor laser.

Pump laser light is typically transmitted to the optical amplifier through a single mode fiber. In order to provide optimum coupling efficiency of the light into the fiber, it is generally desirable to narrow the vertical far field angle of the light as much as possible. Unfortunately, reducing the far field angle usually results in adverse effects on other parameters of the laser, such as threshold current and slope efficiency. For example, in a standard double heterostructure AlGaAs/GaAs pump laser operating at 980 nm, the far field angle can be reduced by lowering the Al concentration of the cladding layers which are adjacent to the quantum well active layer. However, this modification also tends to degrade the threshold current and the slope efficiency, and can also lead to increased leakage currents.

### SUMMARY OF THE INVENTION

The invention is a semiconductor laser and laser module which includes an active region having a first refractive index, and at least one confinement layer with a second refractive index which is lower than the first refractive index. An anti-guiding layer having a third refractive index which is lower than the second refractive index is positioned so that the confinement layer is between the active region and the anti-guiding layer. A cladding layer having a fourth refractive index, which is greater than the third refractive index is positioned so that the anti-guiding layer, is between the cladding layer and the confinement layer.

In accordance with another aspect, the invention is a method of forming a semiconductor laser which includes forming an active region having a first refractive index over a semiconductor substrate, and forming a confinement layer having a second refractive index over the active region. An anti-guiding layer having a third refractive index which is less than the second refractive index is formed over the confinement layer, and a cladding layer having a fourth refractive index which is greater than the third refractive index is formed over the anti-guiding layer.

### BRIEF DESCRIPTION OF THE FIGURES

These and other features of the invention are delineated in detail in the following description. In the drawing;

FIG. 1 is a schematic diagram of a typical optical system, which may incorporate the invention;

FIG. 2 is a schematic cross sectional view of a typical laser package, which may be incorporated into the system of FIG. 1;

FIG. 3 is an enlarged view of a portion of the laser package of FIG. 2;

FIG. 4 is a cross sectional view of a semiconductor laser incorporating features of the invention in accordance with one embodiment;

FIG. 5 is a diagram of the refractive indices of the structure of FIG. 4;

FIGS. 6-8 are graphs of confinement factor (Gamma) and far field angle for various embodiments of the invention.

It will be appreciated that, for purposes of illustration, these Figures are not necessarily drawn to scale.

### DETAILED DESCRIPTION

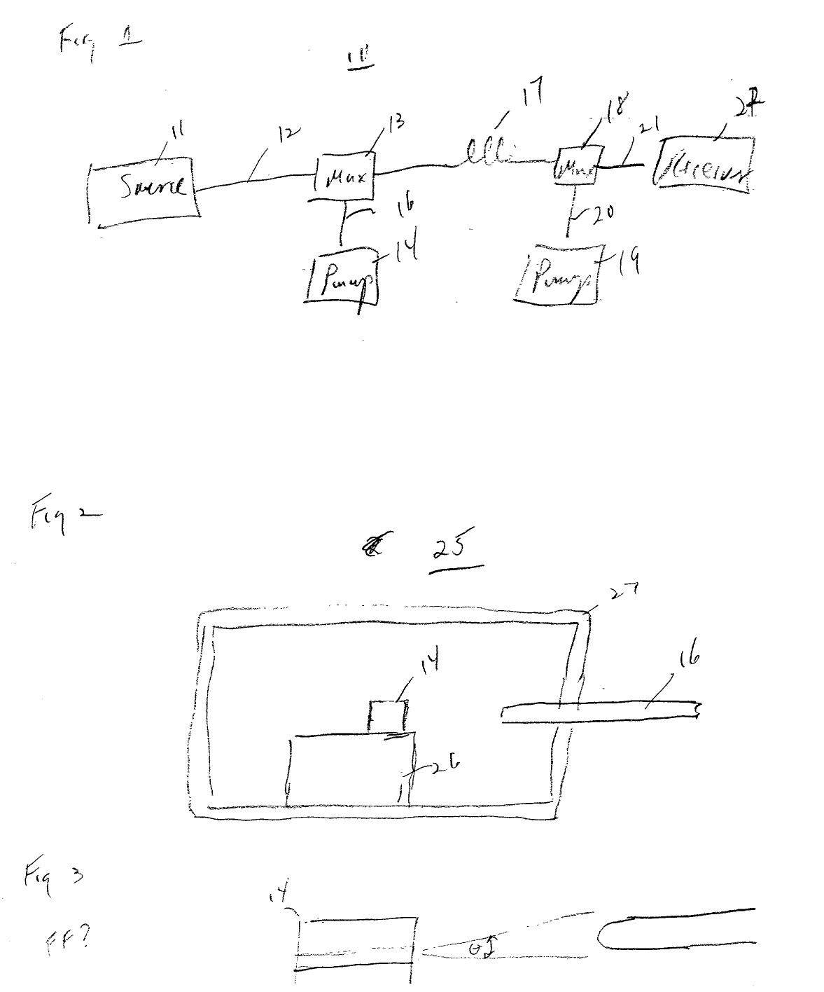

FIG. 1 illustrates a typical optical system, 10, which may include the inventive features. An optical source, 11, provides a signal which is typically several wavelengths in a range about 1550 nm. The source is usually one or more semiconductor lasers such as standard Distributed Feedback (DFB) or Distributed Bragg Reflector (DBR) lasers. The signal is transmitted by an optical fiber, 12, to a multiplexer, 13. Light from a pump laser, 14, which typically has a wavelength of 980 nm is transmitted to the multiplexer, 13, by means of a single mode optical fiber, 16. The combined signal light and pump light are transmitted to an optical amplifier, 17, which is typically an Erbium Doped Fiber Amplifier (EDFA), but could also be a Raman amplifier. The signal light is amplified and transmitted to another multiplexer, 18. The multiplexer, 18, also receives light from a second pump laser, 19, which typically has a wavelength of 1480 nm. The light from the second pump is transmitted to the multiplexer 18, by means of optical fiber, 20, and then on to the EDFA, 17. The signal light is transmitted to a receiver, 22, typically by means of an optical fiber, 21.

It will be appreciated that the diagram of FIG. 1 omits several components, such as optical isolators, which are usually included in an optical system. Also, it may not be necessary to include two pump lasers as shown operating at different wavelengths. Rather, a single pump laser may be sufficient.

FIG. 2 illustrates a simple package design for a laser pump module, 25. The laser, 14, is typically mounted on a platform, 26, which is on the bottom surface of a hermetic enclosure, 27. The optical fiber, 16, with or without a lens, extends through the enclosure and is aligned with the laser, 14, so as to receive the light emanating therefrom. Other elements usually included in the package, such as backface monitoring components, drivers and temperature control devices, are omitted for the sake of clarity.

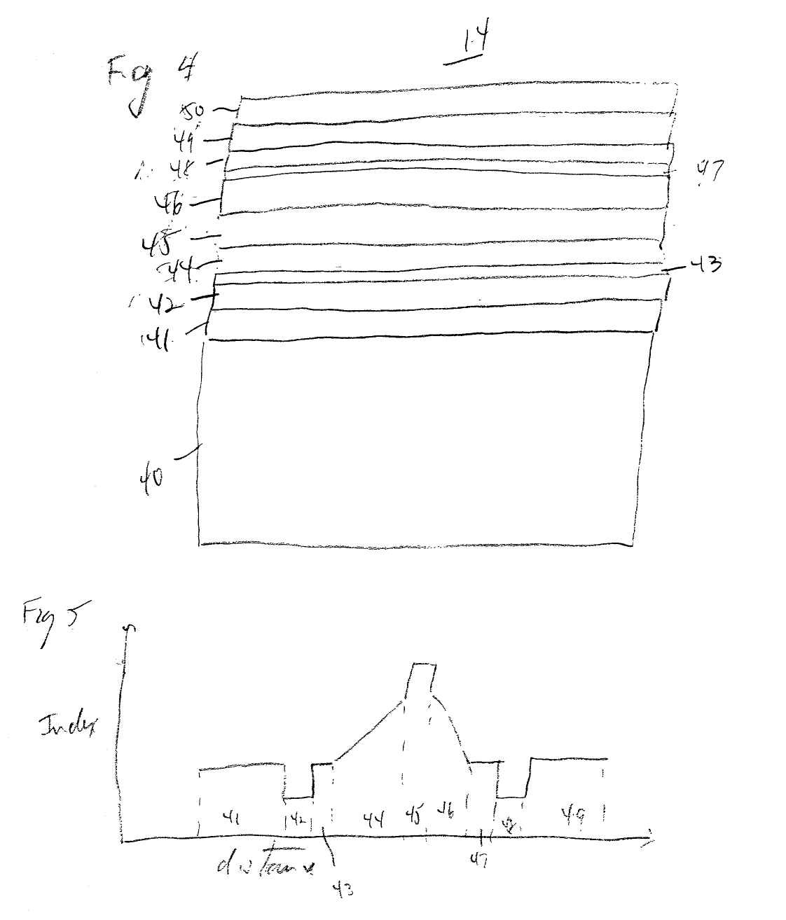

It will be appreciated that an important design consideration is the efficient coupling of the light from the laser to the fiber. This efficiency can be improved by narrowing the far field angle of the laser light, i.e. the angle θ of divergence of the laser light as illustrated in the enlarged view of FIG. 3.

FIG. 4 illustrates one embodiment of a laser structure, 14, with a narrowed far field angle, and, consequently, improved coupling efficiency. The structure is built on a substrate, 40, which in this example, comprises GaAs. A series of epitaxial layers, to be described, are formed on a major surface of the substrate. In this example, the layers are formed by molecular beam epitaxy (MBE), but other techniques could be employed. The first layer, 41, is a cladding layer which comprises AlGaAs and typically has a thickness of 1-3 microns. In this example, the layer, 41, has a refractive index of approximately 3.45. As known in the art, a cladding layer functions to confine the optical mode to the active region (to be described).

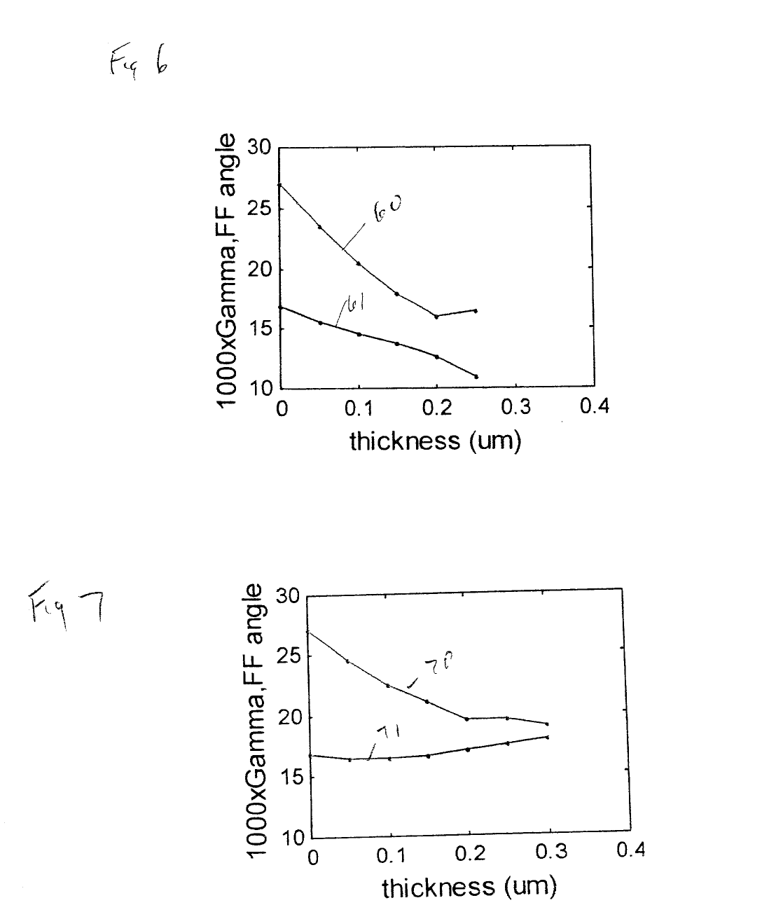

Formed on the cladding layer, 41, is an anti-guiding layer, 42, which in this example comprises AlGaAs and has a thickness of approximately 10-200 nm. As understood in this application, an “anti-guiding” layer is one which has a refractive index less than that of the layers adjacent to it in the structure. Thus, as illustrated in FIG. 5, the refractive index of layer, 42, is less than the refractive index of layer 41, and less than the refractive index of layer, 43, to be described. (For examples of lasers employing anti-guiding layers, see U.S. Pat. No. Re 36,431 issued to Muro et al, and U.S. Pat. No. 5,438,585 issued to Armour, et al.) More details regarding this layer are given below.

Formed on the anti-guiding layer, 42, is an optional spacer layer, 43, which in this example comprises AlGaAs. Formed on the spacer layer is a standard graded Separate Confinement Layer (SCL), 44, which in this example comprises AlGaAs with a varying amount of aluminum to produce the graded refractive index profile illustrated in FIG. 5 (i.e., where the refractive index of layer 44 increases in a direction away from the spacer layer, 43). As known in the art an SCL layer functions primarily to confine charge carriers to the active region.

An active region, 45, is formed on the SCL layer, 45. As known in the art, the laser light is produced in this region as the result of recombination of charge carriers. In this example, the region comprises a series of alternating quantum well and barrier layers comprising InGaAs/AlGaAs. As illustrated in FIG. 5, this region has the highest refractive index in the structure, which is typically greater than 3.6.

Formed successively over the active region are a further SCL layer, 46, spacer layer, 47, anti-guiding layer, 48, and cladding layer, 49. These layers can be (but need not be) identical to their corresponding layers 41-44 in thickness and composition, except for having an opposite conductivity type. Finally, a cap layer, 50, in this example comprising GaAs with a thickness of 0.1 micron is formed on the cladding layer, 50. Appropriate electrodes (not shown) are also formed on the top and bottom of the structure.

While not being bound by any theory, it is believed that placement of anti-guiding layers, 42 and 48, between the SCL layers, 44 and 46, respectively, and the cladding layers, 41 and 49, respectively, and in close proximity to their respective SCL layers, 44 and 46, respectively, pulls a portion of the optical beam outside of the SCL layers. This widens the beam in the near field, resulting in a narrowing of the far field angle as the light enters the optical fiber. While the embodiment described above uses two anti-guiding layers, it will be appreciated that a single such layer could also have beneficial effects.

In one example, applicant employed as the anti-guiding layers, 42 and 48, AlGaAs with an aluminum concentration which was higher than that of the cladding layers, 41 and 49. In particular, the cladding layers had a 28 percent aluminum concentration, while the anti-guiding layers had a 40 percent aluminum concentration. No spacer layers were employed. As illustrated in FIG. 6, the far field angle, curve 60, is lowered from approximately 27 degrees with no anti-guiding layers to approximately 17 degrees with anti-guiding layer thicknesses of 0.2 microns. However, there is also some loss of optical confinement (Gamma) as indicated by curve 61. While adequate for some applications, it is usually preferred to avoid such loss of confinement.

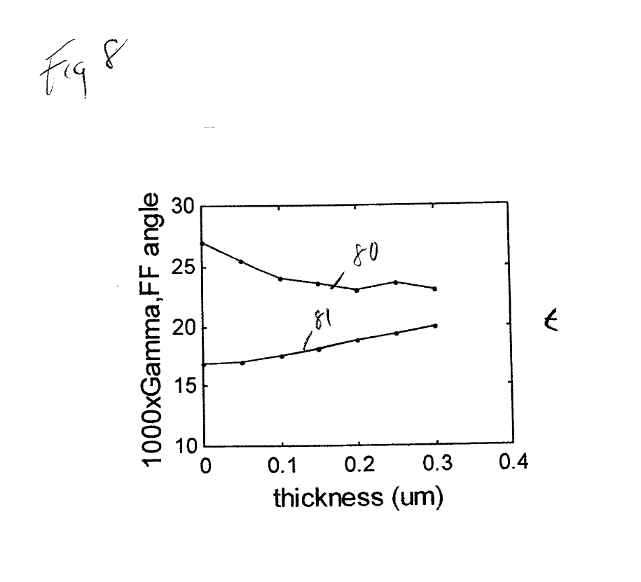

Consequently, in a presently preferred embodiment, spacer layers, 43 and 47 of FIGS. 4 and 5, were introduced. These spacer layers can be, but need not be, identical to the cladding layers, 41 and 49. As illustrated in FIG. 7, for a spacer layer thickness of approximately 500 angstroms, (50 nm) the far field angle, curve 70, is again reduced to below 20 degrees with anti-guiding layer thicknesses of 0.2 microns, but the optical confinement (Gamma) changes very little. In fact, as illustrated in FIG. 8, with a spacer layer thickness of approximately 1000 angstroms (100 nm), the optical confinement increases (curve 81), although far field angle (curve 80) is not reduced as much as the previous example.

Increasing the aluminum concentration in the anti-guiding layers to approximately 40 percent is expected to give an even further reduction in far field angle. For example, with no spacer layers, anti-guiding layer thicknesses of approximately 2000 angstroms (200 nm) is expected to give the lowest far field angle. Spacer layer thicknesses of 500 angstroms (50 nm) and anti-guiding layer thicknesses of approximately 3000 angstroms (300 nm) are expected to give moderate far field angle improvement and Gamma. Increasing the spacer layer thicknesses to 1000 angstroms (100 nm) with anti-guiding layer thicknesses again at 3000 angstroms (300 nm) is expected to give the best Gamma.

In view of these considerations, it is generally preferred to have the aluminum concentration of the anti-guiding layers in the range 20 to 40 percent. Concentrations above 40 percent may introduce problems with doping and non-radiative recombination centers, although such higher concentrations may be usable for certain applications. The thicknesses of the anti-guiding layers are preferably in the range 10 to 200 nm. Spacer layer thicknesses are preferably in the range 0 to 100 nm.

Various modifications of the invention as described are possible. For example, the SCL layers, 44 and 46, need not have a graded index of retraction, but could have a constant or stepped index. Further, the invention is applicable to other types of lasers, such as InP-based lasers useful for pumping Raman amplifiers. In that case, InP could be used as an anti-ginding layer, while InGaAsP could be used for the remaining layers.

What is claimed is:

1. A semiconductor laser comprising:
an active region having a first refractive index;
at least one confinement layer with a second refractive index which is lower than the first refractive index;
an anti-guiding layer having a third refractive index which is lower than the second refractive index and is positioned so that the confinement layer is between the active region and the anti-guiding layer; and
a cladding layer having a fourth refractive index which is greater than the third refractive index and is positioned so that the anti-guiding layer is between the cladding layer and the confinement layer.

2. The laser according to claim 1 further comprising a spacer layer having a fifth refractive index greater than the third refractive index and positioned between the anti-guiding layer and the confinement layer.

3. The laser according to claim 1 wherein light from the active region of the laser has a far field angle of less than 20 degrees.

4. The laser according to claim 1 wherein the thickness of the anti-guiding layer is within the range 10 to 200 nm.

5. The laser according to claim 1 wherein the anti-guiding layer has a metal composition in the range 20 to 40 percent.

6. The laser according to claim 5 wherein the metal is aluminum.

7. The laser according to claim 1 wherein the anti-guiding layer comprises AlGaAs.

8. The laser according to claim 2 wherein the spacer layer comprises AlGaAs.

9. The laser according to claim 2 wherein the spacer layer has a thickness within the range 0 to 100 nm.

10. The laser according to claim 1 wherein the confinement layer has a graded refractive index.

11. A semiconductor laser comprising:
an active region comprising InGaAs and having a first refractive index;
at least two confinement layers positioned on either side of the active region, said layers comprising AlGaAs with a second, graded refractive index which is lower than the first refractive index;
at least two anti-guiding layers comprising AlGaAs having a third refractive index which is lower than the second refractive index and each positioned so that the confinement layers are between the active region and respective anti-guiding layers, the anti-guiding layers having an aluminum concentration in the range 20 to 40 percent and a thickness in the range 10 to 200 nm;
at least two spacer layers having a fifth refractive index greater than the third refractive index and each positioned between respective anti-guiding layers and confinement layers, said spacer layers comprising AlGaAs and having a thickness within the range 0 to 100 nm; and
at least two cladding layers having a fourth refractive index which is greater than the third refractive index and each positioned so that the anti-guiding layers are between respective cladding layers and confinement layers,
light from said laser having a far field angle of less than 20 degrees.

12. A laser module comprising a semiconductor laser mounted within an enclosure, and an optical fiber aligned with the laser so that light from the laser enters the fiber with a certain far field angle, the laser comprising:
an active region having a first refractive index;
at least one confinement layer with a second refractive index which is lower than the first refractive index;
an anti-guiding layer having a third refractive index which is lower than the second refractive index and is positioned so that the confinement layer is between the active region and the anti-guiding layer; and
a cladding layer having a fourth refractive index which is greater than the third refractive index and is positioned so that the anti-guiding layer is between the cladding layer and the confinement layer.

13. The module according to claim 12 wherein the far field angle is less than 20 degrees.

14. A method of forming a semiconductor laser comprising:
forming an active region having a first refractive index over a semiconductor substrate;
forming a confinement layer having a second refractive index over the active region;
forming an anti-guiding layer having a third refractive index which is less than the second refractive index over the confinement layer; and
forming a cladding layer having a fourth refractive index which is greater than the third refractive index over the anti-guiding layer.

15. The method according to claim 14 further comprising forming a spacer layer having a fifth refractive index greater than the third refractive index and positioned between the confinement layer and the anti-guiding layer.

16. The method according to claim 14 wherein the layers are formed by epitaxial growth.

17. The method according to claim 14 wherein the anti-guiding layer is formed to a thickness within the range 10 to 200 nm.

18. The method according to claim 15 wherein the spacer layer is formed to a thickness within the range 0 to 100 nm.

19. The method according to claim 14 wherein the anti-guiding layer is formed with a composition comprising AlGaAs, and the concentration is within the range 20 to 40 percent.
